(19) United States
(12) Patent Application Publication
(10) Pub. No.: US 2016/0240751 A1
(43) Pub. Date: Aug. 18, 2016

(54) LIGHT EMITTING DEVICE AND MANUFACTURING METHOD THEREOF

(71) Applicant: Genesis Photonics Inc., Tainan City (TW)

(72) Inventors: Shao-Ying Ting, Tainan City (TW); Kuan-Chieh Huang, New Taipei City (TW); Jing-En Huang, Tainan City (TW); Yi-Ru Huang, Tainan City (TW)

(21) Appl. No.: 15/045,471

(22) Filed: Feb. 17, 2016

Related U.S. Application Data
(60) Provisional application No. 62/116,923, filed on Feb. 17, 2015.

(51) Int. Cl. H01L 33/52; H01L 33/50; H01L 33/46

(52) U.S. Cl. CPC H01L 33/52; H01L 33/46; H01L 33/507; H01L 2933/005; H01L 2933/0058; H01L 2933/0025

(57) ABSTRACT

A light-emitting device including a light-emitting unit, a packaging sealant, a transparent layer, and a reflective structure is provided. The light-emitting unit has at least one epitaxial layer and two electrodes correspondingly formed on the epitaxial layer. The epitaxial layer has a top surface, a bottom surface on which the two electrodes are exposed, and a side surface connecting the bottom surface and the top surface. The packaging sealant is formed on the top surface and the side surface of the epitaxial layer. The transparent layer is disposed on the packaging sealant and located above the top surface of the epitaxial layer. The reflective structure is disposed surrounding the side surface of the epitaxial layer and formed on the packaging sealant. A manufacturing method of the above light-emitting device is further provided.

This application claims the benefit of U.S. Provisional application Ser. No. 62/116,923, filed Feb. 17, 2015, the disclosure of which is incorporated by reference herein in its entirety.

### TECHNICAL FIELD

The disclosure relates in general to a light-emitting device and a manufacturing method thereof, and more particularly to a light-emitting diode (LED) capable of increasing forward luminance and a manufacturing method thereof.

### BACKGROUND

Refer to FIG. 1. Conventional LED packaging structure 1 includes a packaging cup 11, an LED chip 12, two wires 13, and a packaging sealant 14.

The packaging cup 11 has reflective property and includes a packaging groove 110 facing upwards and a lead frame 113 having a first lead 111 and a second lead 112 separated from each other for electrically connecting to the exterior. The LED chip 12, bonded on the lead frame 113 and disposed inside the packaging groove 110, includes two electrodes 123. The wires 13 are made of metal with excellent conductivity such as gold or silver for electrically connecting the two electrodes 123 of the LED chip 12 to the first lead 111 and the second lead 112 respectively. The packaging sealant 14 is interposed to the packaging groove 110 to seal the opening of the packaging groove 110.

The packaging cup 11 of the conventional LED packaging structure 1 has reflective property and reflects the light emitted from the LED chip 12. However, due to the gap existing between the LED chip 12 and the inner surface of the packaging cup 11, the optical path of the reflected light increases, and optical loss occurs as reflected, and accordingly the efficiency of light extraction deteriorates. Besides, the opening of the packaging cup 11 would increase the light output angle.

### SUMMARY

According to one embodiment of the invention, a light-emitting device is provided. The light-emitting device has a reduced divergence angle for forward light and an increased uniformity of luminance.

Therefore, the light-emitting device of the invention includes a light-emitting unit, a packaging sealant, a transparent layer, and a reflective structure.

The light-emitting unit has at least one epitaxial layer which can illuminate by way of electroluminescence, and two electrodes correspondingly formed on the epitaxial layer. The epitaxial layer has a top surface, a bottom surface on which the two electrodes are exposed, and a side surface connecting the bottom surface and the top surface.

The packaging sealant is formed on the top surface and the side surface of the epitaxial layer.

The transparent layer is disposed on the packaging sealant and located above the top surface of the epitaxial layer.

The reflective structure is disposed surrounding the side surface of the epitaxial layer and formed on the packaging sealant.

According to another embodiment of the invention, a manufacturing method of light-emitting device is provided. The method includes following steps:

At least one light-emitting device is disposed on a substrate, wherein the light-emitting device has an epitaxial structure and two electrodes.

A packaging sealant is formed on the substrate, wherein the packaging sealant covers the epitaxial structure and exposes the two electrodes.

A transparent layer is formed on the packaging sealant.

A reflective structure is formed at least on a surface of the packaging sealant.

With the reflective structure surrounding the side surface of the epitaxial layer being directly disposed on the packaging sealant, the light emitted from the epitaxial layer can be directly reflected by the reflective structure and emitted to the outside, and the optical loss and the emitting angle of the light-emitting device can be effectively reduced.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a conventional LED packaging structure.

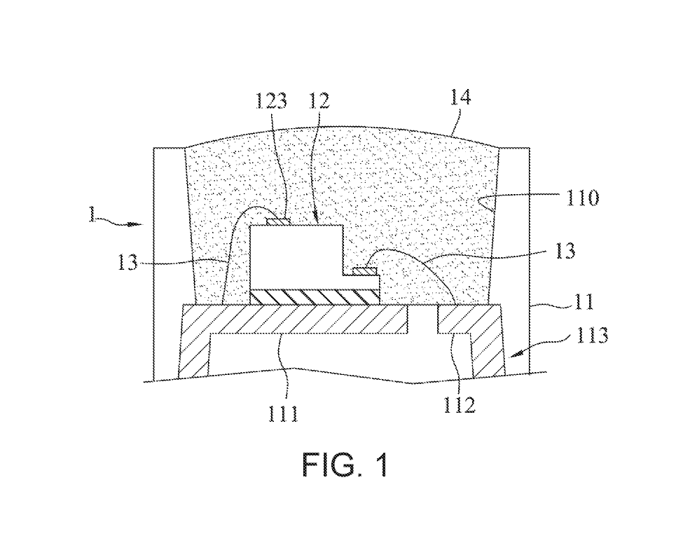

FIG. 2 is a schematic diagram of a light-emitting device according to a first embodiment of the invention.

FIG. 3A is a schematic diagram of a light-emitting device according to a second embodiment of the invention.

FIG. 3B is a schematic diagram of an LED according to a third embodiment of the invention.

FIG. 4 is a schematic diagram of a light-emitting device according to a fourth embodiment of the invention.

FIG. 5 is a schematic diagram of a light-emitting device according to a fifth embodiment of the invention.

### DETAILED DESCRIPTION

It should be noted that in the embodiments of the invention disclosed below, similar or identical elements are designated by the same reference numeral.

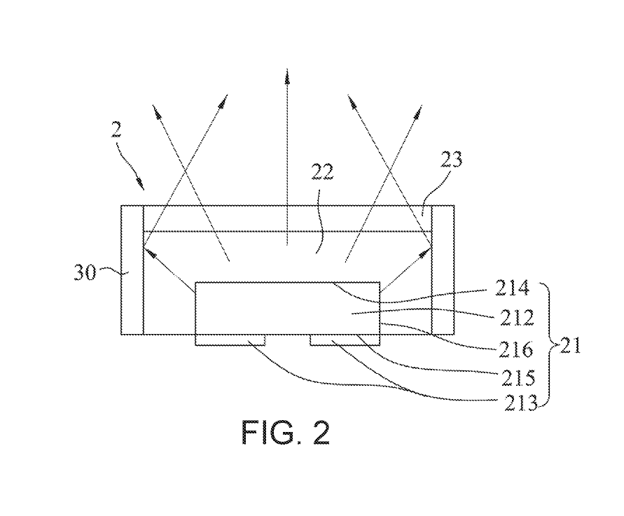

Refer to FIG. 2. The light-emitting device according to a first embodiment of the invention includes a light-emitting unit 21, a packaging sealant 22, a transparent layer 23, and a reflective structure 30.

The light-emitting unit 21 is disposed on one surface of a substrate (not illustrated) and includes an epitaxial layer 212 and two electrodes 213. The epitaxial layer 212, which can illuminate and generate an optical energy by way of electroluminescence, has a top surface 214, a bottom surface 215, and a side surface 216. The top surface 214 connects the transparent layer 23. The bottom surface 215 is opposite to the top surface 214. The side surface 216 connects the bottom surface 215 and the top surface 214. The two electrodes 213 are disposed on the bottom surface 215.

Specifically, the epitaxial layer 212 can be made of different materials according to the wavelength of the light to be emitted. In the present embodiment, the epitaxial layer 212 has an n-type semiconductor layer, a light-emitting layer formed on partial surface of the n-type semiconductor layer, and a p-type semiconductor layer formed on a surface of the light-emitting layer. The bottom surface 215 is composed of the surfaces of the p-type and the n-type semiconductor layers exposed in the same direction. The two electrodes 213 are formed on the exposed surfaces of the p-type and the n-type semiconductor layers. Since the structure and selection of material of the epitaxial layer 212 are known by a person who has ordinary skill in the technical field and they would not be focused by the invention, detailed descriptions thereof are omitted here.

The packaging sealant 22 is formed on the top surface 214 and the side surface 216 of the epitaxial layer 212.

Specifically, the packaging sealant 22 may be formed of a light-transmissible, organic, and polymer packaging sealant such as epoxy resins, polysiloxane or silicone resin or formed of a light-transmissible and inorganic material such as glass. The packaging sealant 22 may isolate the epitaxial layer 212 from external environment to avoid moisture permeation or other external causes affecting the lifespan of the light-emitting unit 21.

The transparent layer 23 is disposed on a top surface of the packaging sealant 22 and located above the top surface 214 of the epitaxial layer 212 of the light-emitting unit 21. The transparent layer 23 may be formed of a material which is light-transmissible and does not affect the optical property, such as glass, polycarbonate, acrylic, ceramic, or plastic.

The reflective structure 30 surrounds correspondingly to the side surface 216 of the epitaxial layer 212, and is directly formed on a surface of the packaging sealant 22, and extends to the peripheral of the transparent layer 23, such that the packaging sealant 22 is arranged between the reflective structure 30 and the side surface 216 of the epitaxial layer 212 for reflecting the light emitted from the light-emitting unit 21. Since the reflective structure 30 directly reflects the light emitted from the side surface 216 of the epitaxial layer 212, the light generated by the epitaxial layer 212 may only be emitted from the top surface 214, and the emitting angle of the light emitted from the light-emitting unit 21 may be effectively reduced. Preferably, the reflective structure 30 has a reflectivity not smaller than 25%.

Specifically, the reflective structure 30 is for reflecting the light emitted from the side surface 216 of the light-emitting unit 21. The material of the reflective structure 30 is not limited as long as the reflective structure 30 may reflect the light emitted from the light-emitting unit 21. However, when the manufacturing process and cost are taken into consideration, preferably, given that the reflective structure 30 has a reflectivity not smaller than 25%, and may be formed of a binder and a plurality of reflective particles dispersed in the binder. Through the use of the reflective particles, total reflection effect may be increased when the light emitted from the light-emitting unit 21 is reflected by the reflective structure 30. Otherwise, the reflective structure 30 may be formed of a metal with excellent reflective property such as silver, aluminum, platinum and gold, or an alloy. The binder is formed of a material selected from macromolecular resin, acrylic resin, or silicone, or a material obtained by solidifying a light-curing or thermosetting material. The reflective particles are formed of a material selected from metal oxides such as titanium dioxide, zirconium dioxide, barium sulfate, and tantalum pentoxide. Otherwise, the reflective structure 30 may be a Bragg reflector formed by stacking the layers with different reflectivities. In the present embodiment, since the reflective structure 30 extends to the peripheral of the transparent layer 23, the issue of light leakage from side surfaces of the transparent layer 23 may be resolved. Based on practical needs, the reflective structure 30 may be correspondingly formed on the side surface 216 of the epitaxial layer 212 without extending to the peripheral of the transparent layer 23.

It should be noted that the packaging sealant 22 may further include phosphor powder. By adding phosphor powder into the organic materials disclosed above, or, sintering the phosphor powder with glass powder to form packaging sealant 22. Thus, the light emitted from the light-emitting unit 21 can excites the phosphor powder to emit a light with predetermined wavelength for various applications. The packaging sealant 22 of the present invention entirely covers the top surface 214 and the side surface 216 of the epitaxial layer 212. Therefore, if the packaging sealant 22 further includes a phosphor powder, all light emitted from the light-emitting unit 21 would change its color through the phosphor powder of the packaging sealant 22, no matter the light is emitted from the side surface 216 or from the top surface 214. Furthermore, since the reflective structure 30 can repeatedly reflect the light, the excitation efficiency of the phosphor powder may be increased, and the emitting light form the light-emitting unit 21 may be more centralized and more uniform.

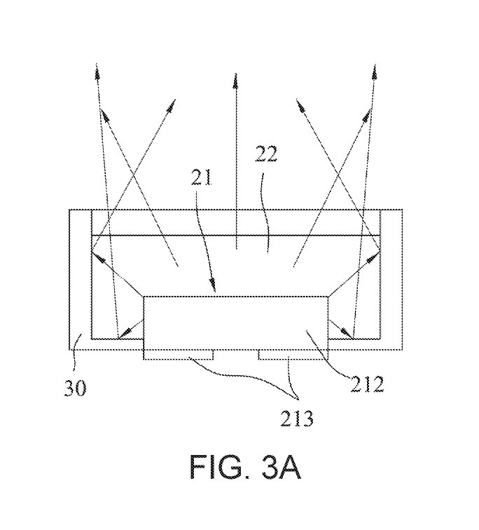

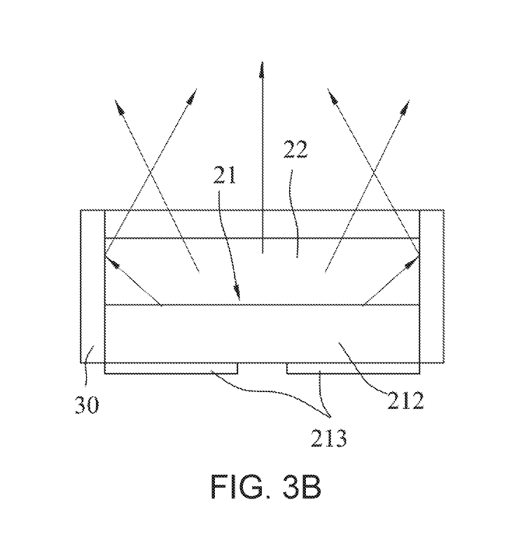

Refer to FIG. 3A. The light-emitting device of the second embodiment is similar to the light-emitting device of the first embodiment. The difference between two embodiments is that the reflective structure 30 is further formed on a bottom surface of the packaging sealant 22. That is, the reflective structure 30 extends downwards and entirely covers the packaging sealant 22, therefore the light emitted from the epitaxial layer 212 of the light-emitting unit 21 toward the bottom surface of the packaging sealant 22 may also be reflected to the transparent layer 23 by the reflective structure 30.

Refer to FIG. 3B. The light-emitting device of the third embodiment is similar to the light-emitting device of the first embodiment. The difference between two embodiment is that the packaging sealant 22 is formed on the top surface of the epitaxial layer 212 and the reflective structure 30 is directly attached to the sides surfaces of the epitaxial layer 212 and the side surfaces of the packaging sealant 22, therefore penetration of the light emitted from the epitaxial layer 212 through the package sealant 22 can be reduced. Instead, the light emitted from the epitaxial layer 212 is directly reflected to the transparent layer 23 by the reflective structure 30 and further emitted thereout.

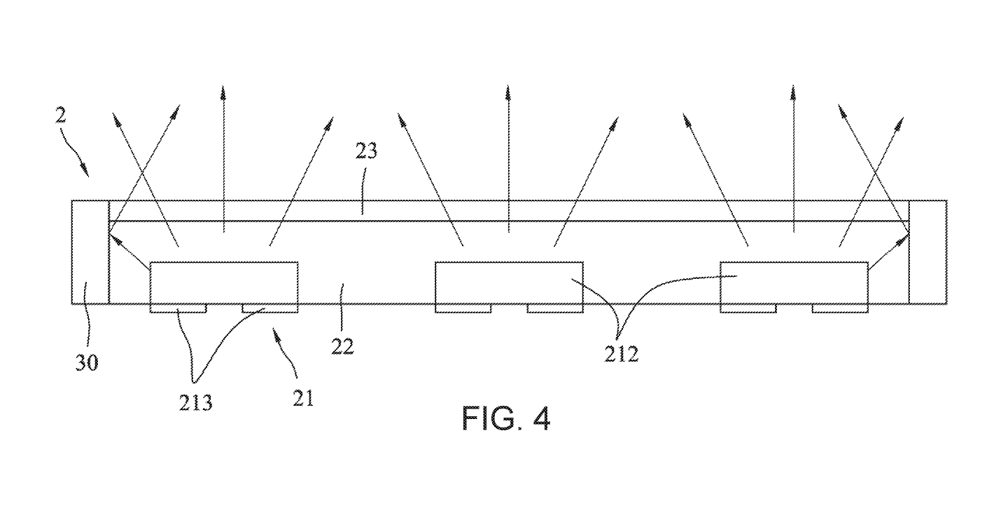

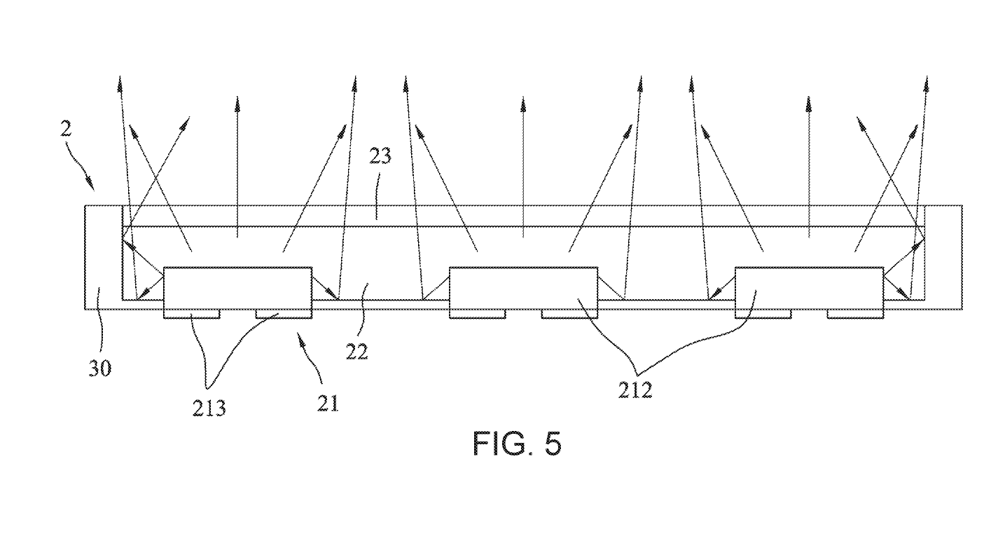

Refer to FIG. 4 and FIG. 5. FIG. 4 and FIG. 5 respectively show a light-emitting device according to a fourth embodiment of the invention and a light-emitting device according to a fifth embodiment of the present invention. The light-emitting devices of the fourth and the fifth embodiments are similar to the light-emitting devices of the first and the second embodiments. The difference is that the light-emitting unit 21 has a plurality of epitaxial layers 212 disposed at intervals in the fourth and the fifth embodiments. In FIG. 4 and FIG. 5, the light-emitting unit 21 has three epitaxial layers 212 disposed at intervals. When the light-emitting unit 21 has a plurality of epitaxial layers 212 disposed at intervals, the reflective structure 30 is disposed surrounding the epitaxial layers 212 and formed on a surface of the packaging sealant 22 and extends to the peripheral of the transparent layer 23. The reflective structure 30 may further extend to the bottom of the packaging sealant 22 to be formed an outermost part of the light-emitting device.

Specifically, the light-emitting device of the above embodiments is manufactured by following steps.

Firstly, a preparation step is performed. A substrate (not illustrated) is provided, and a plurality of light-emitting devices 2 are disposed at intervals on the substrate, wherein, each light-emitting device 2 is composed of a light-emitting unit 21, a packaging sealant 22, and a transparent layer 23.

In details, each light-emitting unit 21 of the light-emitting device 2 may be composed of one epitaxial layer 212 (indicated in FIG. 2, FIG. 3A, FIG. 3B) or more epitaxial layers 212. In FIG. 4 and FIG. 5, each light-emitting unit 21 is composed of three epitaxial layers 212. As shown in FIGS. 4 and 5, when the light-emitting unit 21 is composed of three epitaxial layers 212, the epitaxial layers 212 are disposed at intervals, the packaging sealant 22 is interposed between the surfaces 216 of the epitaxial layers 212 and disposed on the top surface 214 of the epitaxial layers 212, and the transparent layer 23 is connected to the packaging sealant 22 and located above the top surface 214 of the epitaxial layers 212.

When disposing the light-emitting devices 2, the electrodes 213 are faced to and connected to the substrate. Since the technology of disposing the light-emitting devices 2 on the substrate is generally known to a person has ordinary skill in the technical field, detailed descriptions are omitted here.

Then, a step of forming a reflective structure is performed. A reflective structure 30 is directly formed on the packaging sealant 22 corresponding to the side surface 216 of the light-emitting device 2, such that the packaging sealant 22 exists between the reflective structure 30 and the side surface 216 of the epitaxial layer 212 of the light-emitting device 2.

Specifically, in the step of forming a reflective structure, the reflective structure 30 may be obtained by solidifying a reflective gel-type resin interposed to the intervals between the light-emitting devices 2. Also, the reflective structure 30 may be formed of metal or alloy directly deposited in the intervals by way of physical vapor deposition or sputtering. The gel-type resin may be composed of a binder and a plurality of reflective particles dispersed in the binder, wherein, the binder may be a light-curing or thermal setting material, or a polymer resin which is solid at room temperature, or silicone. The reflective particles are formed of a material selected from metal oxide such as titanium dioxide, zirconium dioxide, barium sulfate and tantalum pentoxide. The implementation of the reflective structure 30 depends on actual needs. For example, the reflective structure 30 may be formed on a side surface of the packaging sealant 22 and expose the bottom surface 215 of the packaging sealant 22 as shown in FIG. 4. Otherwise, the reflective structure 30 may cover the entire packaging sealant 22 as shown in FIG. 5.

Finally, a cutting step is performed. A light-emitting device with the reflective structure 30 as shown in FIGS. 2-5 may be obtained by cutting along the intervals by using laser cutting, cutter wheel, diamond knife, tungsten alloy knife, ceramic knife, rubber knife, or resin knife.

According to the light-emitting device and the manufacturing method of the present invention, by disposing the transparent layer 23 on the top surface 214 of the epitaxial layer 212 and by disposing the reflective structure 30 surrounding the side surface 216 of the epitaxial layer 212 and directly on the packaging sealant 22, the emitting angle of the light emitted from the light-emitting unit 21 may be effectively reduced and the uniformity of the light may be increased. Since the reflective structure 30 is directly disposed on the packaging sealant 22, the penetration of reflected light may be effectively decreased, light loss occurs during the reflection is reduced, and the efficiency of light extraction is increased accordingly. Thus, the purpose of the invention can be achieved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting device, comprising:
a light-emitting unit having at least one epitaxial layer and two electrodes correspondingly formed on the epitaxial layer, wherein the epitaxial layer has a top surface, a bottom surface on which the two electrodes are exposed, and a side surface connecting the bottom surface and the top surface;
a packaging sealant at least formed on the top surface of the epitaxial layer;
a transparent layer disposed on the packaging sealant and the top surface of the epitaxial layer; and
a reflective structure disposed surrounding the side surface of the epitaxial layer and formed on the packaging sealant.

2. The light-emitting device according to claim 1, wherein the packaging sealant is further formed on the side surface of the epitaxial layer, and the reflective structure is formed on a surface of the packaging sealant and surrounds the epitaxial layers and extends to the peripheral of the transparent layer.

3. The light-emitting device according to claim 2, wherein the packaging sealant has a top surface and a bottom surface, the transparent layer is formed on the top surface of the packaging sealant, and the reflective structure is further formed on the bottom surface of the packaging sealant.

4. The light-emitting device according to claim 1, wherein the reflective structure is formed of a binder and a plurality of reflective particles dispersed in the binder.

5. The light-emitting device according to claim 4, wherein the reflective particles are formed of a material selected from a group composed of titanium dioxide, zirconium dioxide, barium sulfate, and tantalum pentoxide.

6. The light-emitting device according to claim 4, wherein the binder is formed of a material selected from polymer resin, acrylic resin or silicone.

7. The light-emitting device according to claim 1, wherein the reflective structure is formed of a material selected from silver, aluminum, platinum, gold, or an alloy thereof.

8. The light-emitting device according to claim 1, wherein the reflective structure is a Bragg reflector.

9. The light-emitting device according to claim 1, wherein the packaging sealant contains phosphor powder.

10. A manufacturing method of light-emitting device, comprising:
disposing at least one light-emitting device on a substrate, wherein the light-emitting device has an epitaxial structure and two electrodes;
forming a packaging sealant on the substrate, wherein the packaging sealant covers the epitaxial structure and exposes the two electrodes;
forming a transparent layer on the packaging sealant; and
forming a reflective structure at least on a surface of the packaging sealant.

11. The manufacturing method of light-emitting device according to claim 10, wherein the packaging sealant comprises a phosphor powder.

12. The manufacturing method of light-emitting device according to claim 10, wherein in the step of disposing at least one light-emitting device on the substrate, a plurality of light-emitting devices are disposed at intervals on the substrate, and in the step of forming the reflective structure, the reflective structure is obtained by solidifying a liquid reflective resin interposed to the intervals.

13. The manufacturing method of light-emitting device according to claim 12, wherein the liquid reflective resin comprises a binder and a plurality of reflective particles dispersed in the binder.

14. The manufacturing method of light-emitting device according to claim 10, wherein in the step of forming the reflective structure, the reflective structure is formed by way of vapor deposition or sputtering.

15. The manufacturing method of light-emitting device according to claim 12, further comprising a step of cutting along the intervals to obtain the light-emitting device with the reflective structure.
